(19) United States
(12) Patent Application Publication
(10) Pub. No.: US 2016/0225650 A1
(43) Pub. Date: Aug. 4, 2016

(54) SUBSTRATE HOLDING DEVICE AND SEMICONDUCTOR DEVICE MANUFACTURING METHOD

(71) Applicant: Kabushiki Kaisha Toshiba, Minato-ku (JP)

(72) Inventors: Nobuhiro KOMINE, Nagoya (JP); Taketo KURIYAMA, Kuwana (JP)

(73) Assignee: Kabushiki Kaisha Toshiba, Minato-ku (JP)

(21) Appl. No.: 14/695,449

(22) Filed: Apr. 24, 2015

(30) Foreign Application Priority Data
Jan. 30, 2015 (JP) 2015-016894

(51) Int. Cl. H01L 21/68; H01L 21/683; H01L 21/02; H01L 21/66

(52) U.S. Cl. CPC H01L 21/68; H01L 22/12; H01L 21/683; H01L 21/02005; H01L 21/6838

(57) ABSTRACT

According to one embodiment, there is provided a substrate holding device, in which, when a substrate is mounted on a chuck main body, gas is exhausted from a space between the substrate and a bottom face part, to hold the substrate by suction. The chuck main body includes a plurality of pins fixed to the bottom face part in a mounting area for a substrate. Two or more movable bottom portions are disposed to cover the mounting area for the substrate and to be movable in an extending direction of the pins, in a state where the pins are inserted in the movable bottom portions.

### CROSS-REFERENCE TO RELATED APPLICATIONS

This application is based upon and claims the benefit of priority from Japanese Patent Application No. 2015-016894, filed on Jan. 30, 2015; the entire contents of which are incorporated herein by reference.

### FIELD

Embodiments described herein relate generally to a substrate holding device and a semiconductor device manufacturing method.

### BACKGROUND

In manufacturing a semiconductor device, there is a case where a semiconductor wafer is deformed by receiving a stress, depending on a film formed on the semiconductor wafer. For example, in the case of a NAND type flash memory having a planar shape, residual stresses generated in the in-plane direction of a semiconductor wafer are isotropic, and so the semiconductor wafer is deformed into a bowl shape or umbrella shape. Further, in the case of a NAND type flash memory having a three-dimensional shape in which memory elements are three-dimensionally arranged, the memory cell region and the peripheral circuit region have different sectional structures. Consequently, residual stresses generated in the in-plane direction of a semiconductor wafer tend to be anisotropic, and so the semiconductor wafer is distorted into a saddle shape in some cases.

If a semiconductor wafer has been deformed as described above, when the semiconductor wafer is placed on a stage in a semiconductor manufacturing apparatus, such as a light exposure apparatus, and is held by vacuum suction, the semiconductor wafer cannot be held in a normal state, because of a decrease in holding force applied thereto. As a result, a process performed in the semiconductor manufacturing apparatus is adversely affected.

### BRIEF DESCRIPTION OF THE DRAWINGS

FIG. 1 is a view schematically showing an example of a configuration of a semiconductor manufacturing apparatus including a substrate holding device according to a first embodiment;

FIGS. 2A and 2B comprise views schematically showing a configuration of a stage according to the first embodiment;

FIGS. 3A to 3C comprise views schematically showing an example of a configuration of a movable bottom portion according to the first embodiment;

FIG. 4 is a flow chart showing an example of a sequence of a substrate holding method and a semiconductor device manufacturing method according to the first embodiment;

FIGS. 5A to 5C comprise views showing an example of a case where a wafer is deformed in a bowl shape;

FIGS. 6A and 6B comprise views showing an example of a case where a wafer is deformed in an umbrella shape;

FIGS. 7A to 7C comprise views showing an example of a case where a wafer is deformed in a saddle shape;

FIGS. 8A and 8B comprise views showing a configuration of a substrate holding device according to a comparative example;

FIGS. 9A to 9D comprise views showing an example where a wafer is held by vacuum suction on the substrate holding device according to the comparative example;

FIG. 10 is a sectional view schematically showing an example of a state where a wafer is mounted on the substrate holding device according to the first embodiment;

FIGS. 11A to 11D comprise views showing an example of a configuration of a substrate holding device according to a second embodiment;

FIG. 12 is a flow chart showing an example of a substrate holding method according to the second embodiment;

FIGS. 13A and 13B comprise views showing an example of a method of mounting a wafer deformed in a saddle shape;

FIGS. 14A and 14B comprise views showing an example of a method of mounting a wafer deformed in a saddle shape;

FIGS. 15A and 15B comprise views showing another configuration example of the substrate holding device according to the second embodiment; and

FIG. 16 is a view schematically showing an example of a configuration of a semiconductor manufacturing apparatus according to a third embodiment.

### DETAILED DESCRIPTION

According to one embodiment, a substrate holding device includes a chuck main body and movable bottom portions. The chuck main body includes a plurality of pins fixed to a bottom face part in a mounting area for a substrate. The movable bottom portions, the number of which is two or more, are disposed to cover the mounting area for the substrate and to be movable in an extending direction of the pins, in a state where the pins are inserted in the movable bottom portions. When the substrate is mounted on the chuck main body, gas is exhausted from a space between the substrate and the bottom face part, to hold the substrate by suction.

Exemplary embodiments of a substrate holding device and a semiconductor device manufacturing method will be explained below in detail with reference to the accompanying drawings. The present invention is not limited to the following embodiments.

### First Embodiment

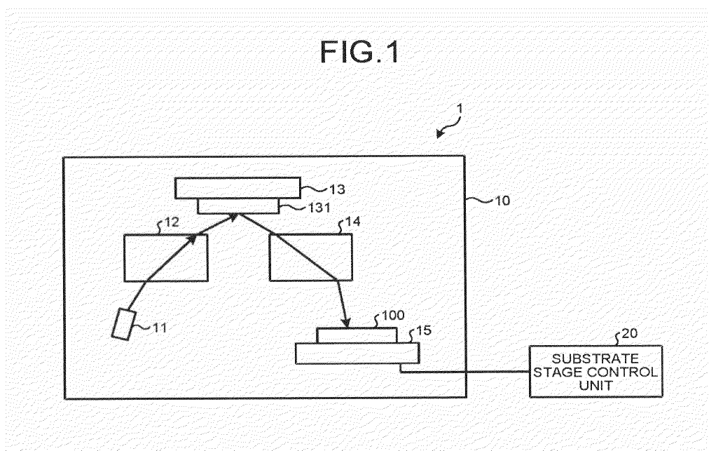

FIG. 1 is a view schematically showing an example of a configuration of a semiconductor manufacturing apparatus including a substrate holding device according to a first embodiment. Here, the semiconductor manufacturing apparatus is exemplified by a light exposure apparatus 1. The light exposure apparatus 1 includes a chamber 10 made of aluminum or stainless steel and configured to form a highly airtight space.

Inside the chamber 10, there is provided a light source 11, an illumination optical system 12, a mask holder 13, a projection optical system 14, and a stage 15 serving as a substrate holding device. The light source 11 is formed of a device for emitting exposure light having a predetermined wavelength.

The illumination optical system 12 irradiates a mask 131 on the mask holder 13 with the exposure light from the light source 11. The illumination optical system 12 includes a plurality of mirrors (not shown) for guiding the exposure light from the light source 11 to the mask 131.

The mask holder 13 holds the mask 131. The mask holder 13 is configured to be movable in a direction parallel with the mask mounting face.

The projection optical system 14 projects the exposure light reflected by the mask 131 onto the stage 15. The projection optical system 14 includes a plurality of mirrors (not shown).

The stage 15 supports a substrate or wafer 100 by a plurality of pins, and fixes the wafer 100 by a vacuum suction mechanism.

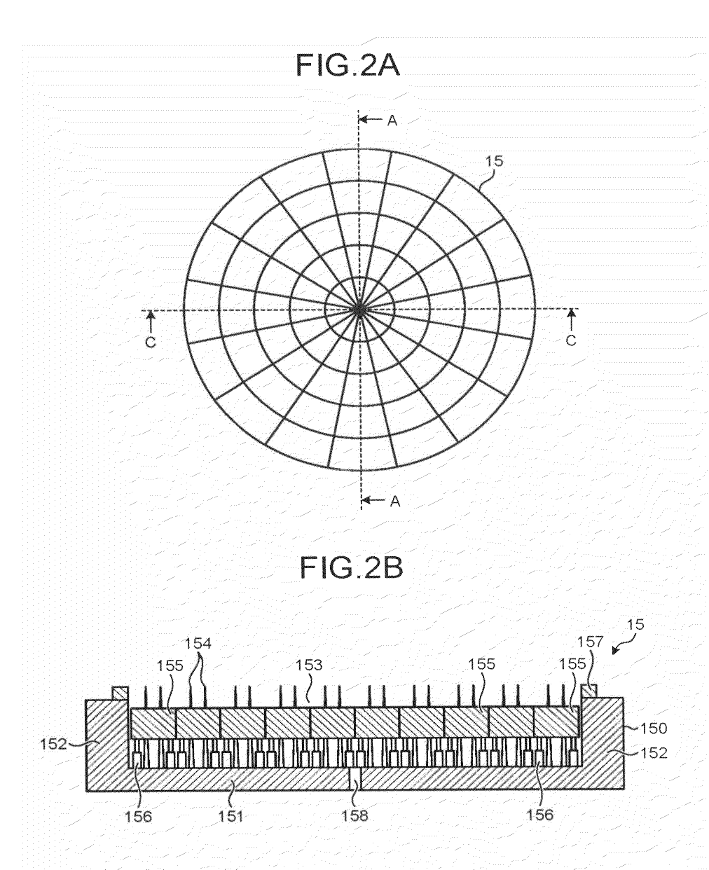

FIGS. 2A and 2B comprise views schematically showing a configuration of the stage according to the first embodiment. FIG. 2A is a top view, and FIG. 25 is a sectional view taken along a line A-A in FIG. 2A. As shown in FIG. 2E, the stage 15 includes a chuck main body 150. The chuck main body 150 includes a bottom face part 151 and a side face part 152 which is disposed around the bottom face part 151 and formed higher than the upper surface of the bottom face part 151. The bottom face part 151 has a circular shape in this example, but it may have another shape. The area surrounded by the bottom face part 151 and the side face part 152 is a recessed area 153. The recessed area 153 is formed at a position corresponding to the mounting position for the wafer 100. The bottom face part 151 includes an exhaust hole 158 formed near the center and penetrating the bottom face part 151 in the thickness direction. The exhaust hole 158 is a single hole formed near the center of the bottom face part 151 in this example, but it may be formed of a plurality of holes.

Inside the recessed area 153, a plurality of pins 154 are provided. The pins 154 have a predetermined height. Each of the pins 154 has a conical shape. This is intended to reduce a risk of local defocus when a foreign contaminant intervenes between the wafer 100 and the stage 15. Each of the pins 154 has a diameter size of about 0.1 to 1 mm, and a height of about several tens to several hundreds μm. Here, all of the pins 154 have the same height. The pins 154 are arranged at predetermined intervals in a two-dimensional state inside the recessed area 153. The lower ends of the pins 154 are fixed to the bottom face part 151 of the chuck main body 150.

Further, inside the recessed area 153, two or more movable bottom portions 155 are provided. The movable bottom portions 155 are formed by dividing a bottom part fit in the recessed area 153 into two or more portions. In this example, as shown in FIG. 2R, a bottom part having a circular shape is divided by five concentric circles having different radiuses, and is further divided by eight straight lines passing through the center. Consequently, eighty movable bottom portions 155 are provided inside the recessed area 153. The movable bottom portions 155 are supported by the bottom face part 151 through support portions 156.

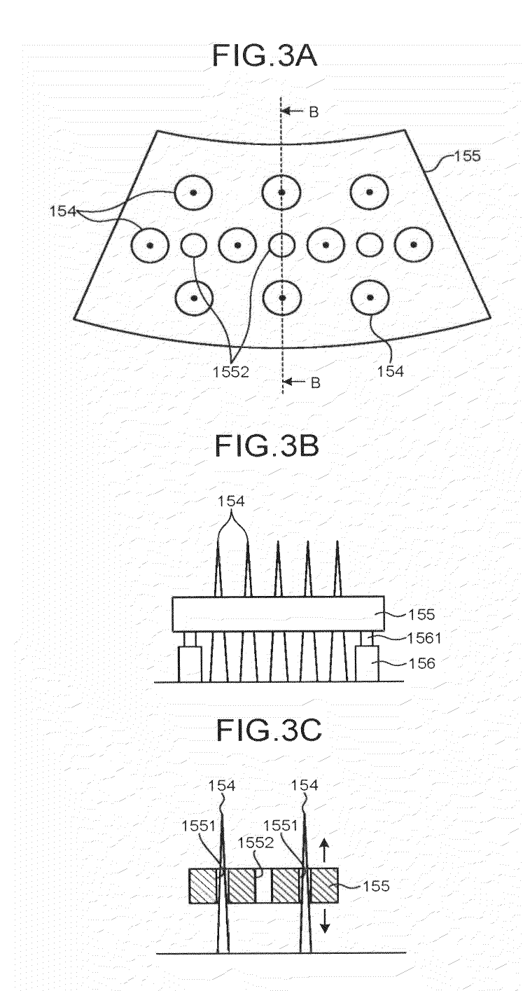

FIGS. 3A to 3C comprise views schematically showing an example of a configuration of a movable bottom portion according to the first embodiment. FIG. 3A is a top view of one movable bottom portion, FIG. 3B is a side view of the movable bottom portion, and FIG. 3C is a sectional view taken along a line B-B in FIG. 3A. This movable bottom portion 155 includes pin insertion holes 1551 and exhaust holes 1552, which penetrate the movable bottom portion 155 in the thickness direction. The pin insertion holes 1551 are formed at positions corresponding to the arrangement positions of the pins 154. The exhaust holes 1552 are formed at positions surrounded by a plurality of pin insertion holes 1551. However, the exhaust holes 1552 may be formed at arbitrary positions.

The support portions 156 support the movable bottom portions 155 above the bottom face part 151. Each of the support portions 156 includes a rod 1561. One end of the rod 1561 is connected to the lower side of the movable bottom portion 155, and the other end of the rod 1561 is connected to an actuator (not shown), such as a motor. When the rods 1561 are moved by the actuators in a direction perpendicular to the lower surface of the bottom face part 151, the position (height) of the upper surface of the movable bottom portion 155 can be changed. Here, the movable bottom portion 155 is moved in a range in which the upper surface of the movable bottom portion 155 is lower than the upper end of the pin 154.

The side face part 152 of the chuck main body 150 is provided with an annular upper wall member 157 disposed on the top. The upper wall member 157 is configured to form a vacuum space between the wafer 100 and the chuck main body 150, and to support the outer peripheral portion of the wafer 100.

As shown in FIG. 1, the stage 15 is equipped with a substrate stage control unit 20. The substrate stage control unit 20 is configured to obtain data about the shape of the wafer 100 to be placed on the stage 15, and to quantize the substrate heights of the wafer 100 at respective regions in the in-plane direction, and thereby to control the positions of the upper surfaces of the movable bottom portions 155 based on the quantized data.

When the wafer 100 is to be mounted on the stage 15 having configuration described above, the substrate stage control unit 20 adjusts the heights of the movable bottom portions 155 inside the recessed area 153, in accordance with the quantized data indicating the shape of the wafer 100 to be mounted. Thereafter, the wafer 100 is mounted on the stage 15 and is held by vacuum suction by use of an exhaust device (not shown).

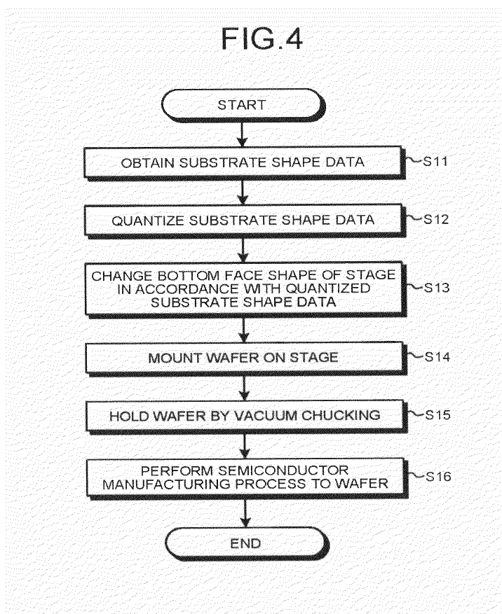

Next, an explanation will be given of a semiconductor device manufacturing method including a step of holding the wafer 100 on the substrate holding device according to the first embodiment. FIG. 4 is a flow chart showing an example of a sequence of a substrate holding method and a semiconductor device manufacturing method according to the first embodiment. At first, substrate shape data is obtained (step S11). The substrate shape data is data indicating the heights of the wafer 100 at respective positions. Based on a reference value set for the heights of the wafer 100, the data indicates how high or how low each of the positions of the wafer 100 is relative to the reference value. The substrate shape data in this case is topography data about the wafer 100. For example, the substrate shape data can be obtained from a result of measurement made by a Fizeau interferometer.

Here, the substrate shape data may be created by use of overlay deviation data. The overlay deviation data is data about positional deviation of overlays, which is caused when circuit patterns are overlaid from below on the wafer 100. The relational expression between the result of overlay deviation and the shape is generally known, and thus the shape of the wafer 100 can be obtained by use of this relational expression.

Further, the substrate shape data may be created by use of alignment data. Also in the case of this alignment data, the shape of the wafer 100 can be obtained as in the case of the overlay deviation data.

Further, the substrate shape data may be created by use of stress data. In this case, data about stresses in the materials of films formed on the wafer 100 is used to estimate distortion generated in the wafer 100 and thereby to create the substrate shape data. Any one of these deviations described above can be used as the substrate shape data.

Then, the substrate shape data is quantized (step S12). The substrate shape data of analog value obtained in the step S11 is converted into substrate shape data of digital value, by use of gradations. Consequently, the substrate shape data becomes discrete value data. For example, in a case where the movable bottom portions 155 have sixteen height levels, the substrate shape data of analog value can be converted into the digital values of sixteen gradations.

Then, the quantized substrate shape data is taken into the semiconductor manufacturing apparatus. For example, the substrate stage control unit 20 reads the quantized substrate shape data. The substrate stage control unit 20 changes the heights of the movable bottom portions 155 of the stage 15, in accordance with the quantized substrate shape data (step S13).

Thereafter, the wafer 100 is transferred into the semiconductor manufacturing apparatus, and the wafer 100 is mounted on the stage 15 (step S14). Then, an exhaust device connected to the exhaust hole 158 of the stage 15 starts exhausting gas, to hold the wafer 100 by vacuum chucking (step S15).

Then, a semiconductor manufacturing process is performed to the wafer 100 inside the semiconductor manufacturing apparatus (step S16). For example, in the case of the light exposure apparatus shown in FIG. 1, a light exposure process is performed to a resist applied on the wafer 100. As a result, the processes are completed.

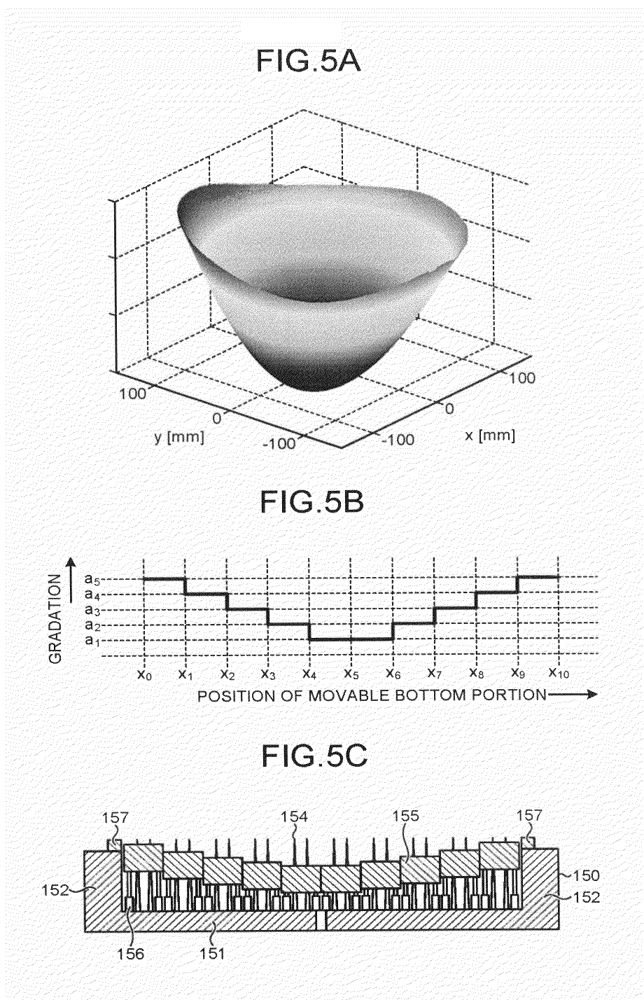

Next, an explanation will be given of an example of adjusting the heights of the movable bottom portions 155 in accordance with the substrate shape data. FIGS. 5A to 5C comprise views showing an example of a case where a wafer is deformed in a bowl shape. FIG. 5A shows an example of the substrate shape data, FIG. 5B shows an example of the quantized substrate shape data, and FIG. 5C shows a state after move of the movable bottom portions. For example, in a case where residual stresses generated in the in-plane direction of a substrate are isotropic, as in a NAND type flash memory having a planar shape, the wafer is distorted into a bowl shape as shown in FIG. 5A.

FIG. 5B shows a state where this substrate shape data is quantized at a position of y=0. In FIG. 5B, the vertical axis denotes gradations at y=0 of the stage 15. For example, in FIG. 5B, the range from x₀ to x₁ represents a site corresponding to a movable bottom portion 155 positioned on the leftmost side. The analog values of the substrate shape data at this site are averaged, and this average value is converted into a gradation, which is assumed to be a₅. Also for the sites corresponding to the other movable bottom portions, such gradations are obtained. Consequently, quantized substrate shape data is obtained such that the gradations have the lowest value of a₁ at the central sites (from x₄ to x₆) and increase stepwise one by one therefrom toward the outer peripheral sites.

In accordance with the quantized substrate shape data shown in FIG. 5B, the substrate stage control unit 20 moves the movable bottom portions 155 in the height direction to be into a state shown in FIG. 5C. The upper surfaces of the movable bottom portions 155 are lower at the central sites, and the upper surfaces of the movable bottom portions 155 are higher at the outer peripheral sites. In this way, the upper surfaces of the movable bottom portions 155 are moved to form the same shape as the warpage of the wafer 100.

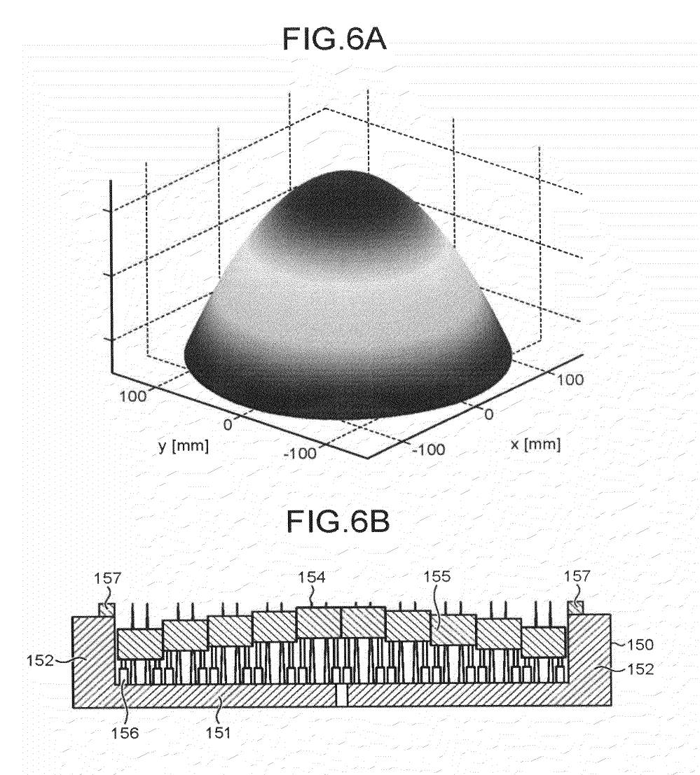

FIGS. 6A and 6B comprise views showing an example of a case where a wafer is deformed in an umbrella shape. FIG. 6A shows an example of the substrate shape data, and FIG. 6B shows a state after move of the movable bottom portions. In this case, as shown in FIG. 6A, the wafer 100 is deformed in an umbrella shape such that it is highest at the center and is lowest at the outer peripheral sides. For example, in a case where residual stresses generated in the in-plane direction of a substrate are isotropic, as in a NAND type flash memory having a planar shape, the wafer is distorted into an umbrella shape as shown in FIG. 6A.

Also in this case, the form of the stage 15 is changed in a similar way as in the case shown in FIGS. 5A to 5C. This result is shown in FIG. 65. As in the deformation of the wafer 100, the upper surfaces of the movable bottom portions 155 are higher at the central sites and are lower at the outer peripheral sites.

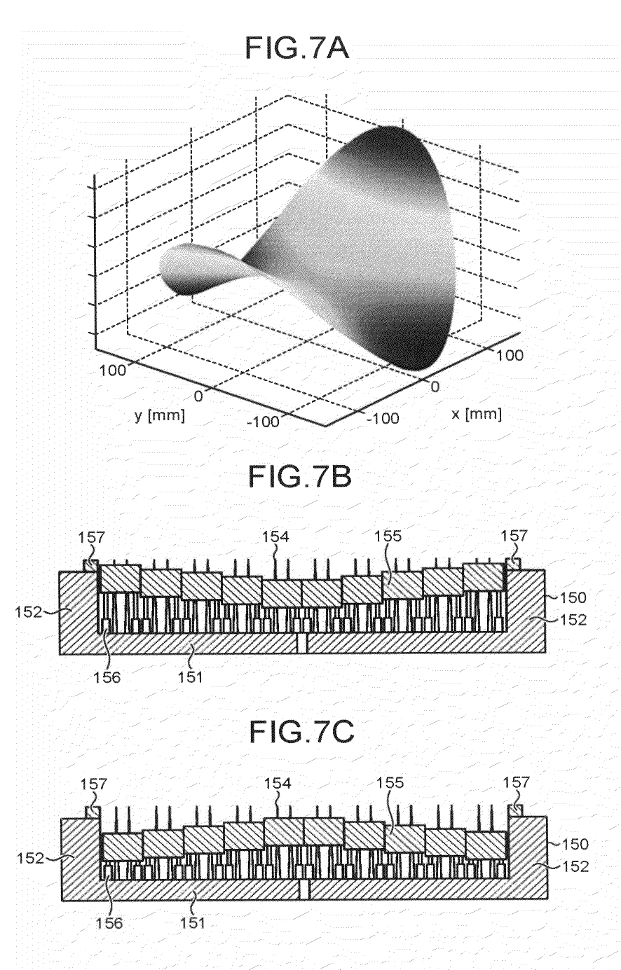

FIGS. 7A to 7C comprise views showing an example of a case where a wafer is deformed in a saddle shape. FIG. 7A shows an example of the substrate shape data, FIG. 75 is a sectional view taken along a line A-A in FIG. 2A, and FIG. 7C is a sectional view taken along a line C-C in FIG. 2A. For example, in the case of a NAND type flash memory having a three-dimensional shape, the wafer 100 has different sectional structures at different positions of the wafer, such as the memory cell region and the peripheral circuit region. Consequently, residual stresses tend to be generated in an anisotropic state. In this case, the wafer 100 is distorted into a saddle shape, as shown in FIG. 7A.

For example, at a position of x=0, the height of the wafer 100 is higher near the central portion and becomes lower toward the outer peripheral sides. However, at a position of y=0, the height of the wafer 100 is lower near the central portion and becomes higher toward the outer peripheral sides. Consequently, at the A-A cross section shown in FIG. 2A, corresponding to y=0, the upper surfaces of the movable bottom portions 155 are moved as shown in FIG. 7B. Further, at the C-C cross section shown in FIG. 2A, corresponding to x=0, the upper surfaces of the movable bottom portions 155 are moved as shown in FIG. 7C.

As described above, the bottom part is formed of a large number of movable bottom portions 155, and thus it can handle a wafer 100 deformed in a more complicated shape.

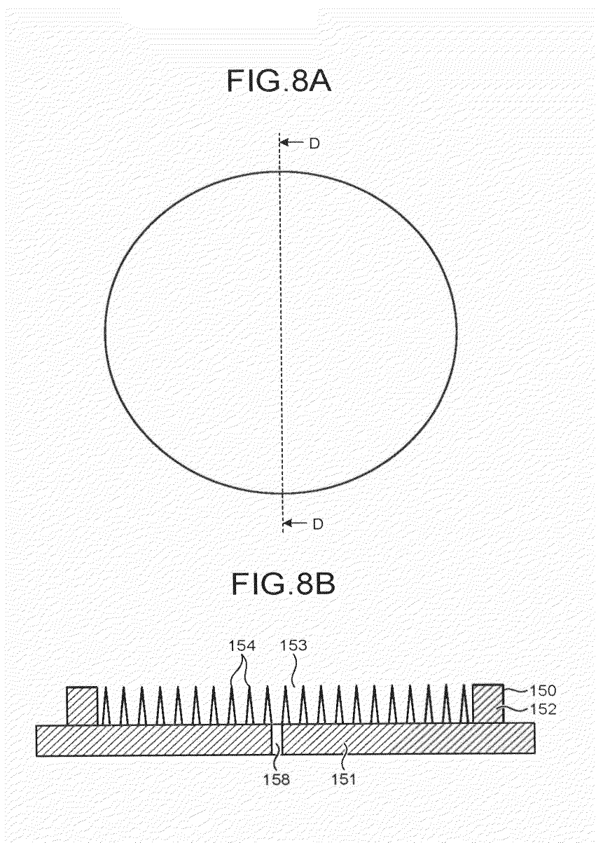

Here, effects obtained by the substrate holding device according to the first embodiment will be explained, as compared with a substrate holding device according to a comparative example. FIGS. 8R and 8B comprise views showing a configuration of the substrate holding device according to the comparative example. FIG. 8A is a top view, and FIG. 8B is a sectional view taken along a line D-D in FIG. 8A.

The substrate holding device according to the comparative example includes a plurality of pins 154 provided inside a recessed area 153 of a chuck main body 150. The pins 154 are fixed to a bottom face part 151 of the chuck main body 150. Further, a side face part 152 is configured to make a vacuum space between the wafer 100 and the bottom face part 151, and to support the outer peripheral portion of a wafer 100. As described above, the substrate holding device according to the comparative example does not include movable bottom portions, but includes the bottom face part 151 as the bottom part of the chuck main body 150. Consequently, the height of the bottom face part 151 cannot be changed depending on the position.

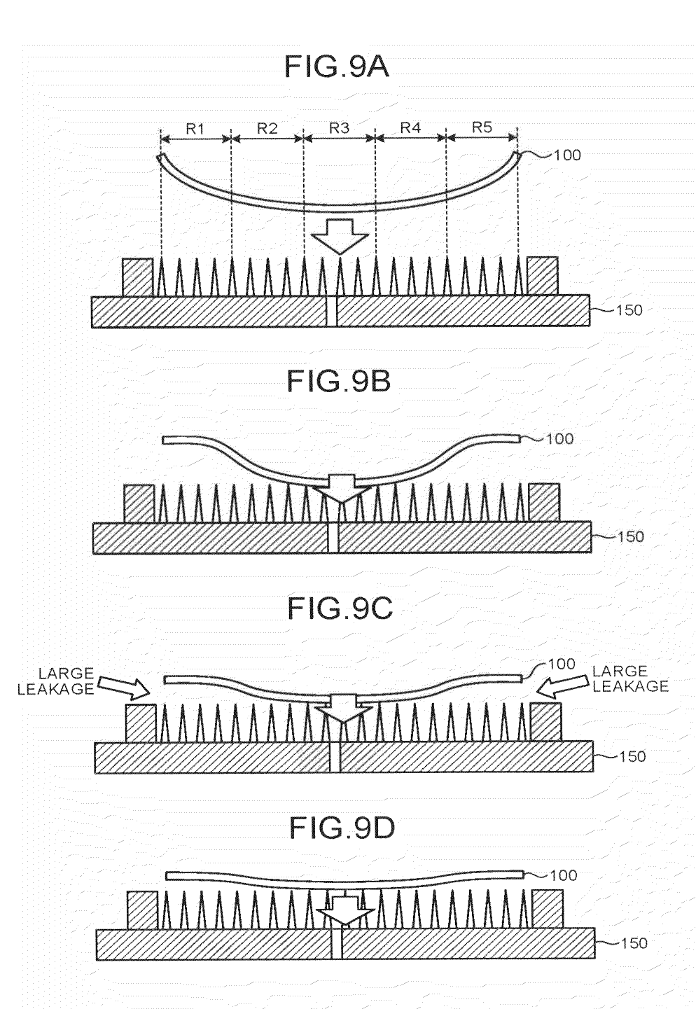

Next, the substrate holding device according to the comparative example will be explained, in relation to a sequence of holding the wafer 100 by vacuum suction. FIGS. 9A to 9D comprise views showing an example where a wafer is held by vacuum suction on the substrate holding device according to the comparative example. At first, as shown in FIG. 9A, the wafer 100 is mounted on the substrate holding device (chuck main body 150). Here, it is assumed that the wafer 100 is strained in a bowl shape. Further, the substrate holding device is considered by dividing it into five regions R1 to R5. These regions R1 to R5 have the same surface areas.

In the substrate holding device according to the comparative example, the height of the bottom face part 151 is constant over all the regions R1 to R5, as described above. Consequently, as regards the volume of a space portion sandwiched between the bottom face part 151 and the wafer 100, that of the region R1 is almost equal to that of the region R5, that of the region R2 is almost equal to that of the region R4, that of the region R1 is larger than that of the region R2, and that of the region R2 is larger than that of the region R3. Accordingly, the amount of gas suction necessary for completion of the suction holding is larger at positions closer to the regions R1 and R5 on the outer peripheral sides where the warpage amount is larger.

Along with the progress of gas exhaust, the position of the wafer 100 is changed, as shown in FIGS. 9B and 9C. Then, as shown in FIG. 9C, the amount of gas suction necessary for completion of the suction holding becomes larger at positions closer to the outer peripheral sides, and so the wafer 100 floats above the upper surface of the substrate holding device. Consequently, the gas leakage becomes larger at the outer peripheral portion of the wafer 100. Thus, as shown in FIG. 9D, the vacuum chuck ends up being incomplete.

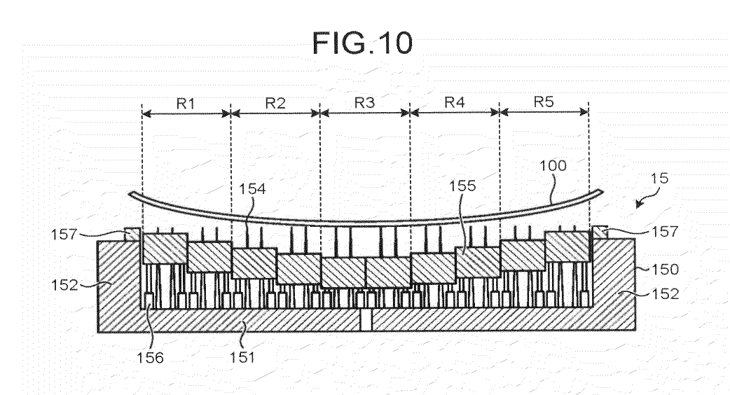

FIG. 10 is a sectional view schematically showing an example of a state where a wafer is mounted on the substrate holding device according to the first embodiment. In a case where the wafer 100 is deformed in a bowl shape, the stage 15 serving as a substrate holding device according to the first embodiment changes the heights of the respective movable bottom portions 155, in accordance with the shape of the wafer 100. Consequently, when the wafer 100 is mounted on the stage 15, the volumes of space portions sandwiched between the wafer 100 and the movable bottom portions 155 are almost equal to each other between the regions R1 to R5. As a result, after the start of gas exhaust, the gas exhaust can be completed at the same time over all the regions R1 to R5. Thus, there is provided an effect capable of accurately holding the wafer 100 by suction. Further, the wafer 100 is held in an almost ideal state, and so the subsequent step of a semiconductor manufacturing process can be performed with high accuracy.

According to the first embodiment, the bottom part of the substrate holding device is divided into two or more regions, so that the heights of the bottom part can be individually changed, in accordance with the shape of a wafer 100 to be mounted. Consequently, the volumes of space portions sandwiched between the bottom part and the wafer 100 are almost equal to each other between the divisional regions, and so the suction holding can be made at the same time over all the regions. As a result, there is provided an effect capable of holding a deformed wafer 100 by suction on the substrate holding device, while planarly reforming it into a normal state. Further, the bottom part of the substrate holding device is divided into a number of portions, and thereby provides an effect capable of handling a wafer 100 deformed in a more complicated shape.

### Second Embodiment

In the first embodiment, an explanation has been given of a substrate holding device that can planarly reform a wafer even if the wafer is deformed in an arbitrary shape. In the second embodiment, an explanation will be given of a substrate holding device that can hold a wafer exemplified by a case where the wafer is deformed in a saddle shape, as shown in FIG. 7A, in a NAND type flash memory having a three-dimensional shape.

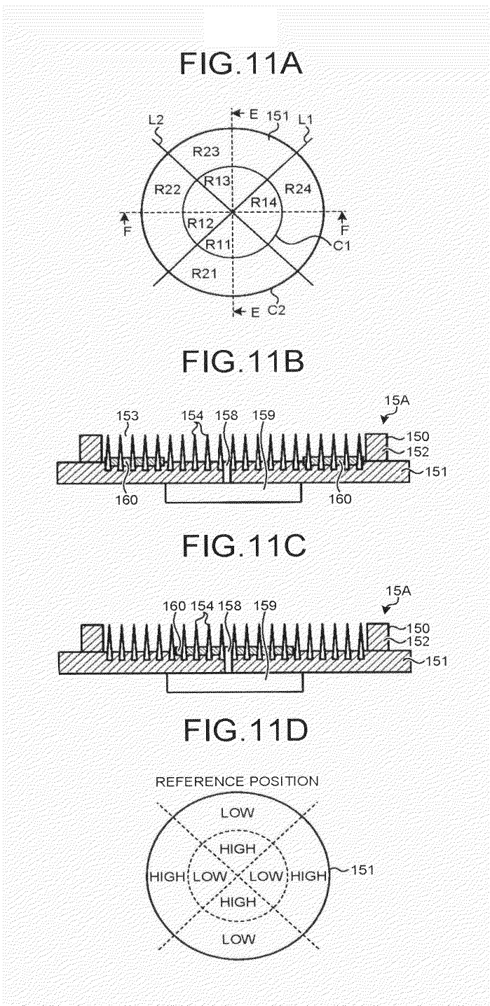

FIGS. 11A to 11D comprise views showing an example of a configuration of the substrate holding device according to the second embodiment. FIG. 11A is a top view, FIG. 11B is a sectional view taken along line E-E in FIG. 11A, FIG. 11C is a sectional view taken along line F-F in FIG. 11A, and FIG. 11D is a view showing high and low features of the bottom face along with the view shown in FIG. 11A. The substrate holding device 15A includes a chuck main body 150. The chuck main body 150 includes a bottom face part 151 and a side face part 152, wherein the side face part 152 is disposed near the outer peripheral portion of the bottom face part 151 and surrounds inside. A recessed area 153 is formed by the bottom face part 151 and the side face part 152. On the bottom face part 151, pins 154 are arranged with the same height. Further, the height of the side face part 152 is adjusted such that the upper surface position of the side face part 152 is flush with the upper end positions of the pins 154.

The bottom face part 151 is divided by two concentric circles C1 and C2 having different radiuses, and is further divided by two straight lines L1 and L2 passing through the center. Consequently, the bottom face part 151 is divided into eight regions R11 to R14 and R21 to R24. Here, the four regions defined by the straight lines L1 and L2 inside the concentric circle C1 are referred to as R11 to R14. Further, the four regions defined by the straight lines L1 and L2 inside the concentric circle C2 and outside the concentric circle C1 are referred to as R21 to R24.

In the second embodiment, the bottom face part 151 of the chuck main body 150 is provided with high floor portions 160, so that the heights of the regions R11, R13, R22, and R24 are higher than the heights of the regions R12, R14, R21, and R23. The high and low relationship of the bottom face is shown in FIG. 11D.

The combination of the regions R11 and R21, the combination of the regions R12 and R22, the combination of the regions R13 and R23, and the combination of the regions R14 and R24 have the same shape as each other, when seen in plan view. Further, the combination of the regions R11 and R21 and the combination of the regions R13 and R23 are categorized as first bottom regions that have the same high and low relationship of the bottom face as each other. The combination of the regions R12 and R22 and the combination of the regions R14 and R24 are categorized as second bottom regions that have the same high and low relationship of the bottom face as each other. Here, the first bottom region and the second bottom region are alternately arranged in the plane.

The heights of the high floor portions 160 are determined in accordance with the degree of deformation of the wafer 100 to be mounted. For example, if the average value of the differences between the maximum value and the minimum value at positions of the wafer 100 to be mounted is 100 μm, the step size is set to 100 μm, and, if it is 200 μm, the step size is set to 200 μm.

Further, a rotary member 159 is provided below the bottom face part 151 of the chuck main body 150. The rotary member 159 is configured to rotate the chuck main body 150 in the in-plane direction. This is intended to adjust the positions of the high floor portions 160, in accordance with the deformation of the wafer 100 in the plane.

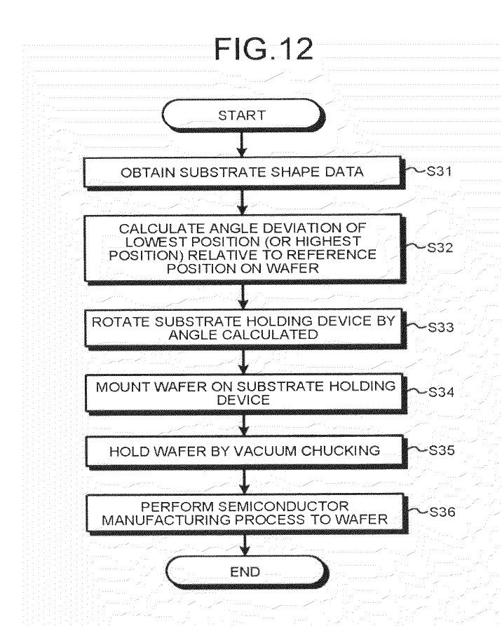

Next, an explanation will be given of an example of a substrate holding method performed in the substrate holding device according to the second embodiment. FIG. 12 is a flow chart showing an example of a substrate holding method according to the second embodiment. At first, substrate shape data is obtained (step S31). Consequently, the substrate shape data is obtained about the wafer 100 deformed in a saddle shape, as shown in FIG. 7A.

Then, the substrate shape data is used to calculate the angle deviation of a lower position on the outer peripheral side (or a higher position on the outer peripheral side) relative to a reference position on the wafer 100 (step S32). For example, the lowest position on the outer peripheral side (or the highest position on the outer peripheral side) is obtained. Then, at the intersection between a line segment, which connects the lowest position on the outer peripheral side (or the highest position on the outer peripheral side) to the center of the wafer 100, and a line segment, which connects the notch of the wafer 100 (the center of the notch) to the center of the wafer 100, their crossing angle is obtained.

Thereafter, the substrate stage control unit 20 rotates the substrate holding device by the angle thus calculated (step S33). Consequently, the positions of the high floor portions 160 of the chuck main body 150 are set to conform to the deformation of the wafer 100 to be mounted. Then, the wafer 100 is mounted on the chuck main body 150 thus rotated (step S34). Thereafter, an exhaust device exhausts gas from inside the recessed area 153 of the chuck main body 150 to hold the wafer 100 by vacuum chucking (step S35). Then, a semiconductor manufacturing process is performed to the wafer 100 (step S36).

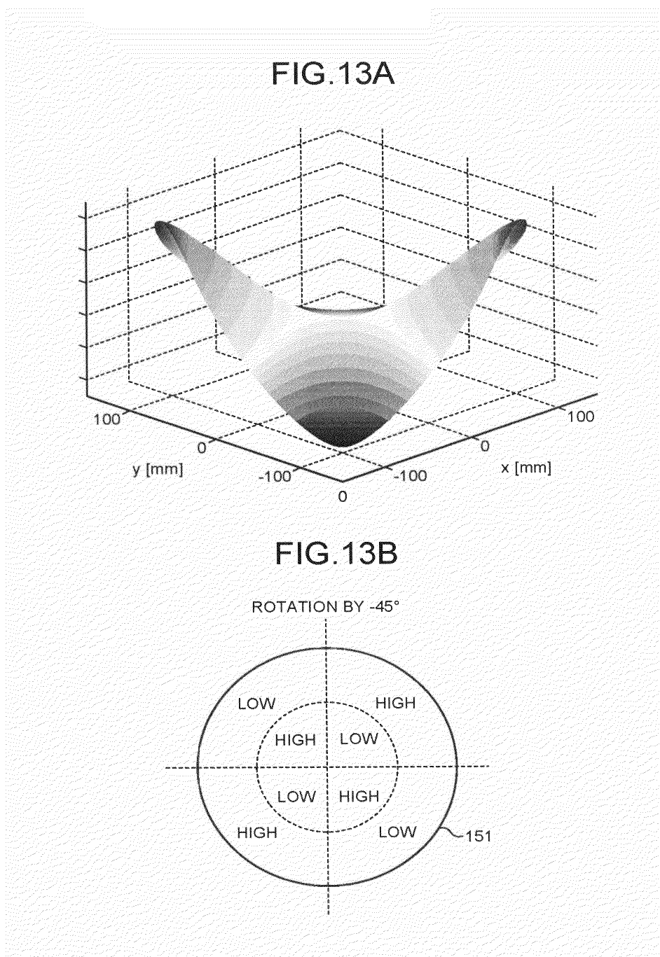

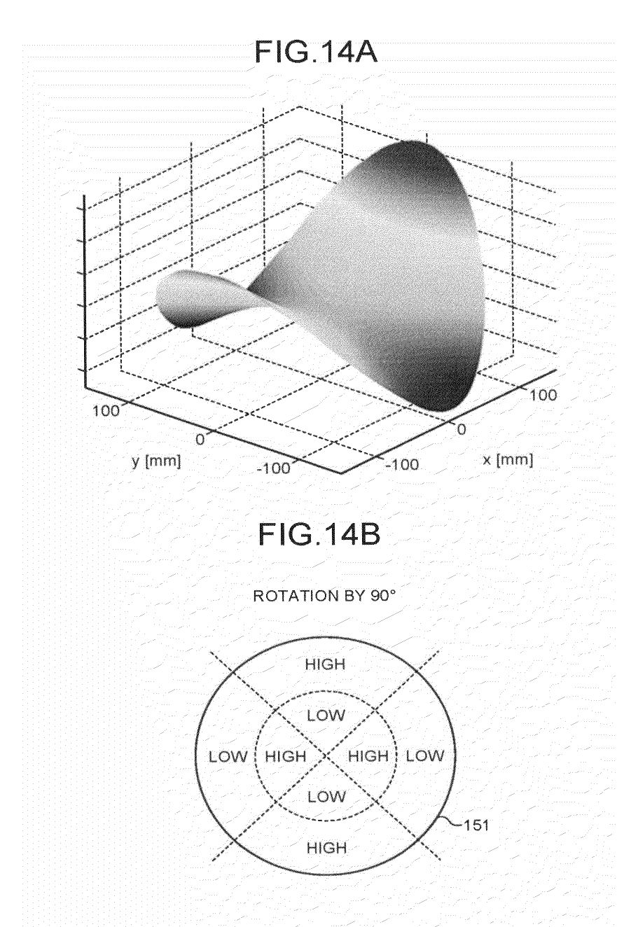

Each of FIGS. 13A, 13B, 14A and 14B comprises views showing an example of a method of mounting a wafer deformed in a saddle shape. FIGS. 13A and 14B show an example of the substrate shape data, and FIGS. 13B and 14B show an example of rotation of the substrate holding device. Here, it is assumed that the substrate holding device has a reference position present at the position shown in FIG. 11D. Further, the reference position of the substrate holding device is set to correspond to a reference position provided on the wafer 100 to be mounted, such as the notch arrangement position.

In the substrate shape data shown in FIG. 13A, it is assumed that the notch is present at a position of y=0. Further, the lowest position on the outer peripheral side is present at a position rotated by 45° in a counter-clockwise direction from the notch position serving as a reference. Accordingly, as shown in FIG. 13B, the substrate stage control unit 20 rotates the substrate holding device by 45° (−45°) in a counterclockwise direction from the state shown in FIG. 11D, and thereby perform positioning.

In the substrate shape data shown in FIG. 14A, it is assumed that the notch is present at a position of y=0. Further, the lowest position on the outer peripheral side is present at a position rotated by 90° in a clockwise direction from the notch position serving as a reference. Accordingly, as shown in FIG. 14B, the substrate stage control unit 20 performs positioning by rotating the substrate holding device by 90° in a clockwise direction from the state shown in FIG. 11D.

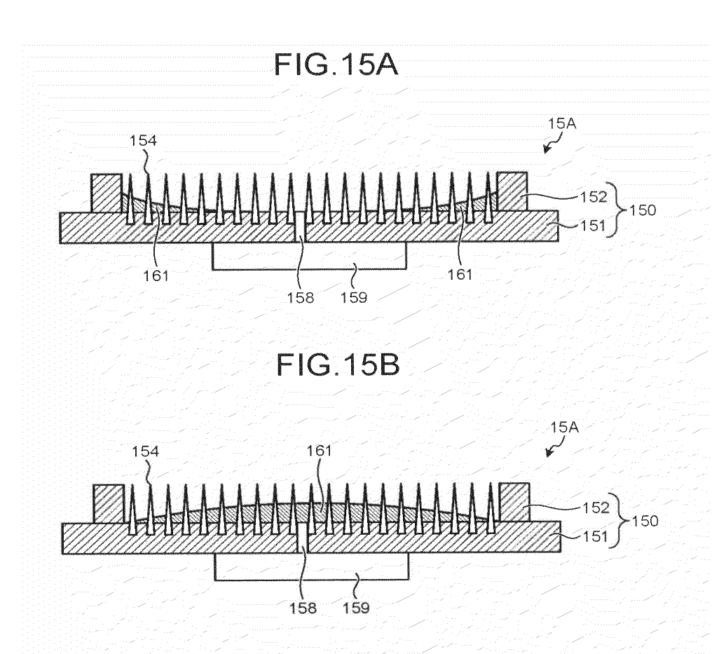

In FIGS. 11B and 11C, the high floor portions 160, each of which has a flat upper surface, are respectively disposed at the regions R11, R13, R22, and R24, but this configuration is not limiting. FIGS. 15A and 15B comprise views showing another configuration example of the substrate holding device according to the second embodiment. FIG. 15A is a view corresponding to the line E-E sectional view shown in FIG. 11A, and FIG. 15B is a view corresponding to the line F-F sectional view shown in FIG. 11A. As shown in FIGS. 15A and 15B, a sloped high floor portion 161 may be provided over the respective regions. In other words, the bottom face part 151 of the chuck main body 150 may be shaped in a saddle shape.

It should be noted that the configuration shown in FIGS. 11A to 11D are a mere example, and this does not limit the embodiment. For example, the bottom face part 151 may be divided by three or more concentric circles having different radiuses, and may be divided by three or more straight lines passing through the center.

According to the second embodiment, the bottom face part 151 of the chuck main body 150 of the substrate holding device has a shape with heights corresponding to a saddle shape, and the chuck main body 150 is configured to be rotatable in the plane. Further, the chuck main body 150 is rotated to set the shape of the bottom face part 151 of the chuck main body 150 to conform to the shape of a wafer 100, and then the wafer 100 deformed in a saddle shape is mounted. Consequently, the volumes of space portions sandwiched between the respective regions of the wafer 100 and the bottom face part 151 are almost equal to each other, and so the suction holding can be made at the same time over all the regions. As a result, there is provided an effect capable of holding a wafer 100, deformed in a saddle shape, by suction on the substrate holding device, while planarly reforming it into a normal state.

### Third Embodiment

The second embodiment is specialized for a case where a wafer is deformed in a saddle shape. However, there is a case a wafer is not deformed in a saddle shape. In the third embodiment, an explanation will be given of a semiconductor manufacturing apparatus that can address such a case.

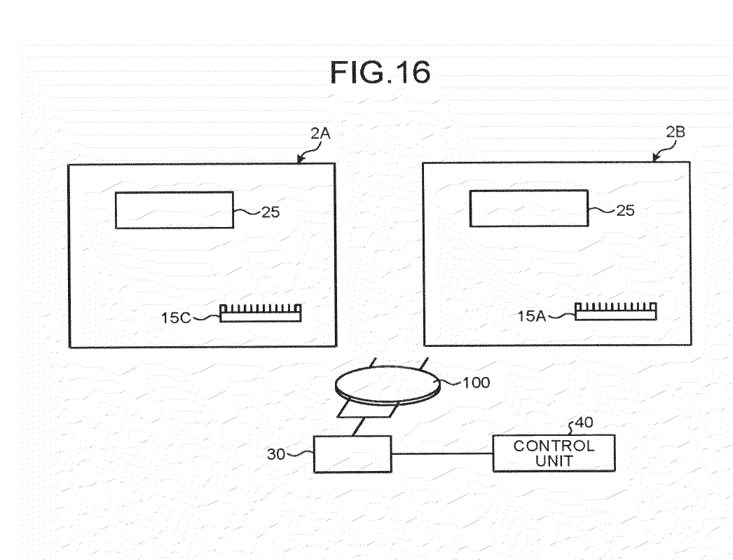

FIG. 16 is a view schematically showing an example of a configuration of a semiconductor manufacturing apparatus according to the third embodiment. As shown in FIG. 16, two semiconductor manufacturing apparatuses 2A and 2B are provided, along with a wafer transfer section 30 and a control unit 40. The semiconductor manufacturing apparatuses 2A and 2D are apparatuses configured to perform semiconductor manufacturing processes of the same type, and each of them includes a semiconductor manufacture processing part 25. For example, the semiconductor manufacture processing part 25 is formed of a light exposure processing part, etching processing part, or film formation processing part. The semiconductor manufacturing apparatuses 2A and 2B respectively include substrate holding devices having different configurations from each other. The semiconductor manufacturing apparatus 2A includes a substrate holding device 15C according to the comparative example, and the semiconductor manufacturing apparatus 2B includes a substrate holding device 15A according to the second embodiment.

In accordance with an instruction from a control unit, the wafer transfer section 30 transfers a wafer 100 to the semiconductor manufacturing apparatus 2A or the semiconductor manufacturing apparatus 2B.

The control unit 40 obtains substrate shape data, and determines, based on the substrate shape data, which one of the semiconductor manufacturing apparatus 2A and the semiconductor manufacturing apparatus 2B to transfer the wafer 100 to. For example, if the difference between the highest position and the lowest position in the substrate shape data is smaller than a predetermined threshold value, the control unit 40 treats the wafer 100 as being not deformed, and sends an instruction to the wafer transfer section 30 to transfer the wafer 100 to the semiconductor manufacturing apparatus 2A. On the other hand, if the difference between the highest position and the lowest position in the substrate shape data is equal to or larger than the predetermined threshold value, the control unit 40 treats the wafer 100 as being deformed in a saddle shape, and sends an instruction to the wafer transfer section 30 to transfer the wafer 100 to the semiconductor manufacturing apparatus 2B.

The wafer 100 is placed in the semiconductor manufacturing apparatus 2B in the same manner as explained in the second embodiment, and so its detailed description will be omitted.

The example described above is provided with the semiconductor manufacturing apparatus 2A configured to hold a wafer 100 considered as being not deformed, and the semiconductor manufacturing apparatus 2B configured to hold a wafer 100 considered as being deformed in a saddle shape. However, this does not limit the embodiment. For example, three or more semiconductor manufacturing apparatuses may be provided. In this case, they are composed of one semiconductor manufacturing apparatus configured to hold a wafer 100 considered as being not deformed, and two semiconductor manufacturing apparatuses configured to hold a wafer 100 considered as being deformed in a saddle shape. In this case, the semiconductor manufacturing apparatuses configured to hold a wafer 100 considered as being deformed in a saddle shape are further categorized, in terms of the difference between the highest position and the lowest position in the substrate shape data, into two types, one of which is to handle a wafer having a difference of 100 μm or less and the other is to handle a wafer having a difference of larger than 100 μm.

According to the third embodiment, the semiconductor manufacturing apparatus configured to hold a wafer 100 considered as being not deformed, and the semiconductor manufacturing apparatus configured to hold a wafer 100 considered as being deformed in a saddle shape are provided, along with the control unit 40 configured to determine, based on the substrate shape data, which one of the semiconductor manufacturing apparatuses to transfer the wafer 100 to. Consequently, there is provided an effect capable of switching the substrate holding devices, in accordance with the degree of deformation of the wafer 100 to be processed.

The substrate holding device described above may be used as a substrate stage in various types of semiconductor manufacturing apparatuses, such as a light exposure apparatus, etching apparatus, and film formation apparatus.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A substrate holding device comprising:
a chuck main body including a plurality of pins fixed to a bottom face part in a mounting area for a substrate; and
two or more movable bottom portions disposed to cover the mounting area for the substrate and to be movable in an extending direction of the pins, in a state where the pins are inserted in the movable bottom portions,
wherein, when the substrate is mounted on the chuck main body, gas is exhausted from a space between the substrate and the bottom face part, to hold the substrate by suction.

2. The substrate holding device according to claim 1, further comprising drive members configured to move the movable bottom portions in the extending direction of the pins.

3. The substrate holding device according to claim 2, wherein each of the drive members includes
a rod having one end connected to corresponding one of the movable bottom portions, and
a motor connected to the other end of the rod.

4. The substrate holding device according to claim 1, wherein the movable bottom portions include exhaust holes penetrating in a thickness direction.

5. The substrate holding device according to claim 1, wherein the chuck main body includes
a side face part disposed around an arrangement area of the plurality of pins, and
an exhaust hole configured to exhaust gas from a space surrounded by the bottom face part and the side face part.

6. The substrate holding device according to claim 1, further comprising a control unit configured to control positions of the movable bottom portions in the extending direction of the pins, based on substrate shape data.

7. The substrate holding device according to claim 6, wherein the control unit is configured to determine the positions of the movable bottom portions, such that the volumes per unit surface area of space portions sandwiched between the movable bottom portions and the substrate are equal to each other over the mounting area for the substrate, when the substrate is mounted on the chuck main body.

8. The substrate holding device according to claim 6, wherein the control unit is configured to control the positions of the movable bottom portions, such that upper surfaces of the movable bottom portions do not come into contact with the substrate.

9. The substrate holding device according to claim 6, wherein the substrate shape data is any one of topography data, overlay deviation data, alignment data, and stress data.

10. A substrate holding device comprising:
a chuck main body including a plurality of pins fixed to a bottom face part in a mounting area for a substrate; and
a rotary mechanism configured to rotate the chuck main body in an in-plane direction of the substrate,
wherein the bottom face part is divided into four or more bottom regions having same shape passing through a center of the bottom face part, and
heights of the bottom regions include combination of two or more different conditions.

11. The substrate holding device according to claim 10, wherein the bottom regions includes a first bottom region having bottom face heights that are lower at an outer peripheral side than at a center on the bottom face part, and a second bottom region having bottom face heights that are higher at the outer peripheral side than at the center on the bottom face part.

12. The substrate holding device according to claim 11, wherein the bottom face heights of the bottom regions are changed stepwise.

13. The substrate holding device according to claim 11, wherein the bottom face heights of the bottom regions are changed gradually.

14. The substrate holding device according to claim 11, wherein the first bottom region and the second bottom region are alternately arranged.

15. The substrate holding device according to claim 11, further comprising a control unit configured to rotate the chuck main body, based on substrate shape data, to set a shape of the bottom face part to conform to a shape of the substrate.

16. A semiconductor device manufacturing method comprising:
obtaining substrate shape data;
controlling positions of movable bottom portions of a substrate holding device in an extending direction of pins, based on the substrate shape data, the substrate holding device including a chuck main body including a plurality of pins fixed to a bottom face part in a mounting area for a substrate, and the two or more movable bottom portions disposed to cover the mounting area for the substrate and to be movable in the extending direction of the pins, in a state where the pins are inserted in the movable bottom portions;
mounting the substrate onto the substrate holding device;
exhausting gas from a space between the substrate and the bottom face part and thereby holding the substrate by suction; and
performing a semiconductor manufacturing process to the substrate.

17. The semiconductor device manufacturing method according to claim 16, wherein, in the controlling the positions of the movable bottom portions, the positions of the movable bottom portions are determined such that the volumes per unit surface area of space portions sandwiched between the movable bottom portions and the substrate are equal to each other over the mounting area for the substrate, when the substrate is mounted on the chuck main body.

18. The semiconductor device manufacturing method according to claim 16, wherein, in the controlling the positions of the movable bottom portions, the positions of the movable bottom portions is controlled such that upper surfaces of the movable bottom portions do not come into contact with the substrate.

19. The semiconductor device manufacturing method according to claim 16, wherein the substrate shape data is any one of topography data, overlay deviation data, alignment data, and stress data.

20. The semiconductor device manufacturing method according to claim 16, wherein the semiconductor manufacturing process is any one of a light exposure process, etching process, and film formation process.
